(19) United States
(12) Patent Application Publication
(10) Pub. No.: US 2009/0152607 A1
(43) Pub. Date: Jun. 18, 2009

(54) FERROELECTRIC STACKED-LAYER STRUCTURE, FIELD EFFECT TRANSISTOR, AND FERROELECTRIC CAPACITOR AND FABRICATION METHODS THEREOF

(76) Inventors: Hiroyuki TANAKA, Kyoto (JP); Yoshihisa Kato, Shiga (JP); Yukihiro Kaneko, Osaka (JP)

Correspondence Address: MCDERMOTT WILL & EMERY LLP, 600 13TH STREET, NW, WASHINGTON, DC, 20005-3096, US

(21) Appl. No.: 12/328,275

(22) Filed: Dec. 4, 2008

(30) Foreign Application Priority Data
Dec. 18, 2007 (JP) 2007-326184

(51) Int. Cl. H01L 29/78; H01L 21/04; H01G 4/06; B32B 9/00

(52) U.S. Cl. 257/295; 438/3; 361/321.4; 428/332; 428/699; 257/E21.04; 257/E29.255

(57) ABSTRACT

A ferroelectric stacked-layer structure is fabricated by forming a first polycrystalline ferroelectric film on a polycrystalline or amorphous substrate, and after planarizing a surface of the first ferroelectric film, laminating on the first ferroelectric film a second thin ferroelectric film having the same crystalline structure as the first ferroelectric film. A field effect transistor or a ferroelectric capacitor includes the ferroelectric stacked-layer structure as a gate insulating film or a capacitor film.

### BACKGROUND OF THE INVENTION

The present disclosure relates to a ferroelectric stacked-layer structure and a fabrication method of the same, and to a field effect transistor or a ferroelectric capacitor in which a ferroelectric stacked-layer structure is used for a gate insulating film or a capacitor film and a fabrication method of the same.

Nonvolatile memories can be generally divided into two types: capacitor type and FET (Field Effect Transistor) type in which a gate insulating film is composed of a ferroelectric film.

The structure of the capacitor type is similar to that of DRAM (Dynamic Random Access Memory), in which charge is stored in a ferroelectric capacitor and the state of data, 0 or 1, is distinguished by the polarization direction of the ferroelectric material. Since data stored is destroyed while being read, the data needs to be rewritten. Therefore, the polarization is reversed every time the data is read, which leads to polarization reversal fatigue. Moreover, polarization charge is read by a sense amplifier in this structure; therefore the amount of charge needs to be equal to or greater than the limit amount of charge (typically 100 fC) which the sense amplifier can detect. Polarization charge of a ferroelectric material per area is intrinsic to the ferroelectric material. Hence, as long as the same material is used, a given area is necessary for an electrode even in the case where a finer memory cell is attempted. It is therefore difficult to decrease the capacitor size in accordance with the process rules changing to finer design rules. The capacitor type memories do not lend themselves to an increase in capacity.

On the other hand, data in the FET type ferroelectric memories is read by detecting channel conductivity which varies according to the polarization direction of the ferroelectric film. The data therefore can be read without being destroyed. In addition, the amplitude of an output voltage is increased by the amplifying effect of FET. Microfabrication based on the scaling rules is thus possible. Accordingly, unlike the capacitor type memories, the FET type ferroelectric memories may be greatly downsized.

Conventionally, the following Field Effect Transistors have been proposed in which a ferroelectric film to be a gate insulating film is formed on a silicon substrate and the silicon functions as a channel. These transistors are called MFSFET (Metal Ferroelectric Semiconductor Field Effect Transistor). While capacitor type ferroelectric memories can store data for about ten years, data in the conventional MFSFET disappears in several days. This may result from being unable to obtain an excellent interface between the silicon substrate and the ferroelectric film. To be more specific, the cause may be oxidization of the silicon substrate surface or diffusion of elements into the silicon, which are easily caused by the high temperatures during the formation of the ferroelectric film on the silicon substrate.

Proposed as a solution for this problem is a ferroelectric memory composed of MFSFET using an oxide semiconductor for a semiconductor layer (see Applied Physics Letters, vol. 68, pp. 3650-3652, June 1996 (Document 1) and Applied Physics Letters, vol. 86, pp. 16290-1 to -3, April 2005 (Document 2)). Considering that in general a ferroelectric film is composed of an oxide, no oxidation layer, such as a silicon dioxide film, is formed in the stacked-layer structure where an oxide semiconductor is used as a channel, while such the oxidation layer is formed in the stacked-layer structure where silicon is used as a channel. It is therefore possible to achieve a stable interface state.

FIG. 24A and FIG. 24B are cross sections showing a general structure of MFSFET in which an oxide semiconductor is used as a channel. FIG. 24A illustrates MFSFET having a back gate structure, where a gate electrode 102 is formed below a channel 104 (oxide semiconductor film). FIG. 24B illustrates MFSFET having a top gate structure, where the gate electrode 102 is formed above the channel 104. The reference numerals 101 and 103 denote a substrate and a ferroelectric film, respectively, and 105 and 106 denote source/drain electrodes.

The temperature at which the ferroelectric film 103 is grown needs to be high, usually from 600° C. to 800° C. (see Japanese Journal of Applied Physics, vol. 43, No. 5A, pp. 2651-2654, 2004 and Journal of Applied Physics, vol. 89, p. 6370, May 2001). On the other hand, the temperature at which the oxide semiconductor film 104 is grown may be low, from a room temperature to approximately 500° C. (see Applied Physics Letters, vol. 85, pp. 2541-2543, September 2004 and Applied Physics Letters, vol. 89, pp. 41109-1 to -3, July 2006). Accordingly, a back gate structure is preferable in order to suppress the diffusion of elements or the like and achieve a stable interface state.

The operation of MFSFET is hereinafter described with reference made to FIG. 25 and FIG. 26, taking a back gate structure as an example.

FIG. 25 shows a method for measuring subthreshold characteristics of MFSFET. Modulation of a drain current Id (interface current) is detected by applying a gate voltage Vg to the terminal 110 of the gate electrode 102, grounding the terminal 111 of the source electrode 105, and applying a drain voltage Vd to the terminal 112 of the drain electrode 106.

As shown in FIG. 26A, the polarization direction of the ferroelectric film 103 is downward when a negative voltage is applied to the gate electrode 102. Carriers are swept away due to the polarization, and depletion occurs in the entire semiconductor film 104 (channel). As a result, the semiconductor film 104 is in a high resistance state (OFF state). On the other hand, as shown in FIG. 26B, the polarization direction of the ferroelectric film 103 is upward when a positive voltage is applied to the gate electrode 102. Carriers in the density corresponding to the polarization density are induced at the interface and charge is accumulated. As a result, the semiconductor film 104 is in a low resistance state (ON state). The drain current (interface current), large or small, is made to correspond to binary data “1” or “0.” The structure can thus function as a memory device. Remnant polarization of the ferroelectric film is retained even in the voltage-off state. This achieves a nonvolatile memory.

As a material of the oxide semiconductor film 104 of MFSFET having a back gate structure, Document 1 discloses tin oxide (SnO₂) and Document 2 discloses indium tin oxide (ITO). SnO₂ achieves the ON-OFF ratio of 60, and ITO achieves the ON-OFF ratio of 10⁴. In either case, however, long-time data retaining characteristics are not obtained.

On the other hand, Extended Abstract of 2007 on International Conference of Solid State Devices and Materials, pp. 1156-1157, 2007 discloses the technique of forming MFSFET which has a extremely flat oxide semiconductor/ferroelectric interface by utilizing an oxide epitaxial growth method. Specifically, strontium ruthenium oxide (SrRuO₃) as a gate electrode and lead zirconate titanate (Pb(Zr, Ti)O₃; PZT) as a ferroelectric film are epitaxially grown on a single crystal substrate of strontium titanate (SrTiO₃; STO) cut along a (100) plane. The surface of the ferroelectric film is as planer as an atomic layer. Further, zinc oxide (ZnO) as an oxide semiconductor is grown at a temperature lower than the temperature at which the ferroelectric film is formed to achieve a steep oxide semiconductor/ferroelectric interface. As a result, MFSFET which has the ON-OFF ratio of 10⁴ and long-time data retaining characteristics is obtained.

### SUMMARY OF THE INVENTION

As described in the above, a planar and excellent oxide semiconductor/ferroelectric interface can be obtained through the oxide epitaxial growth method. It is therefore anticipated that the long-time data retaining characteristics may be obtained. However, it is difficult to grow STO single crystals in a large diameter. An STO single crystal semiconductor substrate that is obtainable is about 20 mm square at the largest. Hence, STO single crystals do not lend themselves to mass production. Besides, in the case where a memory device is embedded on CMOS or a transparent memory device is formed on a glass substrate, such memory devices need to be formed on an amorphous film, such as an interlayer insulating film (a silicon dioxide film, for example). It is therefore difficult to use an epitaxial growth method.

An object of the present invention is to provide a ferroelectric film having excellent interface properties and a field effect transistor or a ferroelectric capacitor in which a ferroelectric film having the above interface properties is used and which have excellent electric characteristics.

A method for fabricating a ferroelectric stacked-layer structure according to the present invention includes: (a) forming a first polycrystalline ferroelectric film on a polycrystalline or amorphous substrate; (b) planarizing a surface of the first ferroelectric film; (c) stacking on the planarized first ferroelectric film a second thin ferroelectric film having the same crystalline structure as the first ferroelectric film.

Formed in this way, the second ferroelectric film, provided on the planarized first ferroelectric film, has a planar surface, and because the crystal defect generated on the surface of the first ferroelectric film by the planarization is not exposed on the surface, it is possible to achieve a ferroelectric stacked-layer structure having excellent interface properties with a reduced carrier trap level.

It is also possible to achieve a field effect transistor or a ferroelectric capacitor which has excellent electric characteristics by using the above ferroelectric stacked-layer structure having excellent interface properties for a gate insulating film or a capacitor film.

According to a preferred embodiment, a crystal orientation of the first ferroelectric film and a crystal orientation of the second ferroelectric film are aligned. With this structure, the ferroelectric stacked-layer structure has the same polarization in the entire part. Accordingly, variations in device characteristics due to variations in polarization can be reduced even if the devices are microfabricated.

According to a preferred embodiment, the first ferroelectric film and the second ferroelectric film are formed of the same element, and a thickness of the second ferroelectric film is in a range of 1 nm to 60 nm.

A ferroelectric stacked-layer structure according to the present invention is a ferroelectric stacked-layer structure formed on a polycrystalline or amorphous substrate, including: a first polycrystalline ferroelectric film; and a second thin ferroelectric film stacked on the first ferroelectric film, wherein the first ferroelectric film has a planarized surface, and the second ferroelectric film has the same crystalline structure as the first ferroelectric film.

A method for fabricating a field effect transistor according to the present invention includes: (a) forming a gate electrode on a substrate; (b) forming a first polycrystalline ferroelectric film on the substrate so as to cover the gate electrode; (c) planarizing a surface of the first ferroelectric film; (d) stacking, on the planarized first ferroelectric film, a second thin ferroelectric film having the same crystalline structure as the first ferroelectric film; (e) forming a semiconductor film on the second ferroelectric film; and (f) forming a source/drain electrode on the semiconductor film, wherein the first ferroelectric film and the second ferroelectric film constitute a ferroelectric stacked-layer structure which serves as a gate insulating film of the field effect transistor.

A method for fabricating a ferroelectric capacitor according to the present invention includes: (a) forming a first conductive film on a substrate; (b) forming a first polycrystalline ferroelectric film on the first conductive film; (c) planarizing a surface of the first ferroelectric film; (d) stacking, on the planarized first ferroelectric film, a second thin ferroelectric film having the same crystalline structure as the first ferroelectric film; and (e) forming a second conductive film on the second ferroelectric film, wherein the first ferroelectric film and the second ferroelectric film constitute a ferroelectric stacked-layer structure which serves as a capacitor film of the ferroelectric capacitor.

A field effect transistor according to the present invention is a field effect transistor of which a gate insulating film has a ferroelectric stacked-layer structure, the ferroelectric stacked-layer structure including: a first polycrystalline ferroelectric film; and a second thin ferroelectric film stacked on the first ferroelectric film, wherein the first ferroelectric film has a planarized surface, the second ferroelectric film has the same crystalline structure as the first ferroelectric film, a semiconductor film is further formed on the second ferroelectric film, and an interface between the second ferroelectric film and the semiconductor film serves as a channel of the field effect transistor.

A ferroelectric capacitor according to the present invention is a ferroelectric capacitor of which a capacitor film has a ferroelectric stacked-layer structure, the ferroelectric stacked-layer structure including: a first polycrystalline ferroelectric film; and a second thin ferroelectric film stacked on the first ferroelectric film, wherein the first ferroelectric film has a planarized surface, and the second ferroelectric film has the same crystalline structure as the first ferroelectric film.

According to the present invention, the second ferroelectric film, provided on the planarized first ferroelectric film, has a planar surface with no crystal defect. It is therefore possible to achieve a ferroelectric stacked-layer structure having excellent interface properties with reduced carrier trap level. It is also possible to achieve a field effect transistor or a ferroelectric capacitor which has excellent electric characteristics by using the above ferroelectric stacked-layer structure having excellent interface properties for a gate insulating film or a capacitor film.

### BRIEF DESCRIPTION OF THE DRAWINGS

FIG. 1 is a cross section of the structure of a field effect transistor for explaining a problem to be solved by the present invention.

FIG. 2A is an SEM image of the surface of a PZT film. FIG. 2B shows the surface roughness of the PZT film. FIG. 2C is a graph showing the properties of an interface current.

FIG. 3 is a cross section of the structure of a field effect transistor for explaining a problem to be solved by the present invention.

FIG. 4A is an SEM image of the surface of a PZT film. FIG. 4B shows the surface roughness of the PZT film. FIG. 4C is a graph showing the properties of an interface current.

FIG. 5 is a graph showing the properties of an interface current of a PZT film which is subjected to a heat treatment after polishing.

FIG. 6 is a cross section of the structure of a field effect transistor according to the first embodiment of the present invention.

FIG. 7 is a graph showing the relationship between the thickness and the surface roughness of a second ferroelectric film according to the first embodiment of the present invention.

FIG. 8A to FIG. 8D are cross sections showing the fabrication method of the field effect transistor according to the first embodiment of the present invention.

FIG. 9A to FIG. 9C are cross sections showing the fabrication method of the field effect transistor according to the first embodiment of the present invention.

FIG. 10 shows the X-ray diffraction pattern of a ferroelectric stacked-layer structure according to the first embodiment of the present invention.

FIG. 11 is a graph showing the current-voltage properties of the field effect transistor according to the first embodiment of the present invention.

FIG. 12 is a graph showing the charge accumulation properties of the field effect transistor according to the first embodiment of the present invention.

FIG. 13 is a cross section of the structure of a ferroelectric capacitor according to the second embodiment of the present invention.

FIG. 14A to FIG. 14D are cross sections showing the fabrication method of the ferroelectric capacitor according to the second embodiment of the present invention.

FIG. 15A and FIG. 15B are cross sections showing the fabrication method of the ferroelectric capacitor according to the second embodiment of the present invention.

FIG. 16 is a graph showing the current-voltage properties of the ferroelectric capacitor according to the second embodiment of the present invention.

FIG. 17 is a graph showing the polarization-voltage properties of the ferroelectric capacitor according to the second embodiment of the present invention.

FIG. 18A is a cross section of the structure of a semiconductor memory device according to the third embodiment of the present invention. FIG. 18B is an equivalent circuit of the semiconductor memory device.

FIG. 19A to FIG. 19D are cross sections showing the fabrication method of the semiconductor memory device according to the third embodiment of the present invention.

FIG. 20A to FIG. 20D are cross sections showing the fabrication method of the semiconductor memory device according to the third embodiment of the present invention.

FIG. 21 is a table for explanation of the operation of the semiconductor memory device according to the third embodiment of the present invention.

FIG. 22A and FIG. 22B illustrate write operations of the semiconductor memory device according to the third embodiment of the present invention.

FIG. 23 is an array structure of the semiconductor memory devices according to the third embodiment of the present invention.

FIG. 24A is a cross section of MFSFET having a conventional back gate structure. FIG. 24B is a cross section of MFSFET having a top gate structure.

FIG. 25 illustrates a method for measuring the subthreshold characteristics of MFSFET.

FIG. 26A illustrates the state of depletion and FIG. 26B illustrates the state of charge accumulation, in the write operation of MFSFET.

### DETAILED DESCRIPTION OF THE INVENTION

The inventors of the present invention have found the following findings while researching a technique for forming, on an amorphous film (or a polycrystalline film), MFSFET having an excellent oxide semiconductor/ferroelectric interface.

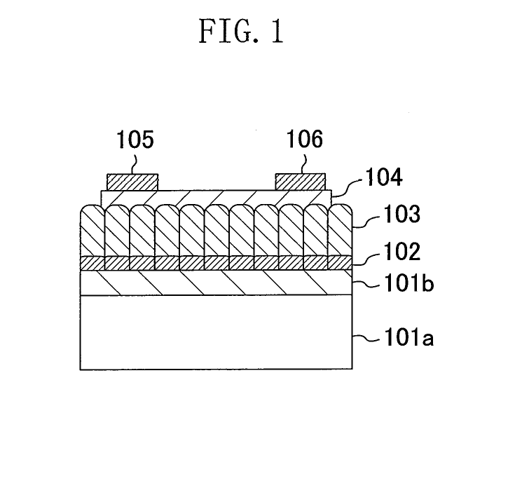

First, an interface current in the structure of FIG. 1, in which MFSFET is formed above an SiO₂ film 101b provided on an Si substrate 101a, examined. The thickness of the SiO₂ film 101b is 30 nm; a gate electrode 102 is a multilayered film of SRO (30 nm)/platinum (200 nm)/titanium (30 nm); a ferroelectric film 103 is a PZT film having a thickness of 450 nm; a semiconductor film 104 is a ZnO film having a thickness of 30 nm; and source/drain electrodes 105 and 106 are a multilayered film of platinum (30 nm)/titanium (30 nm).

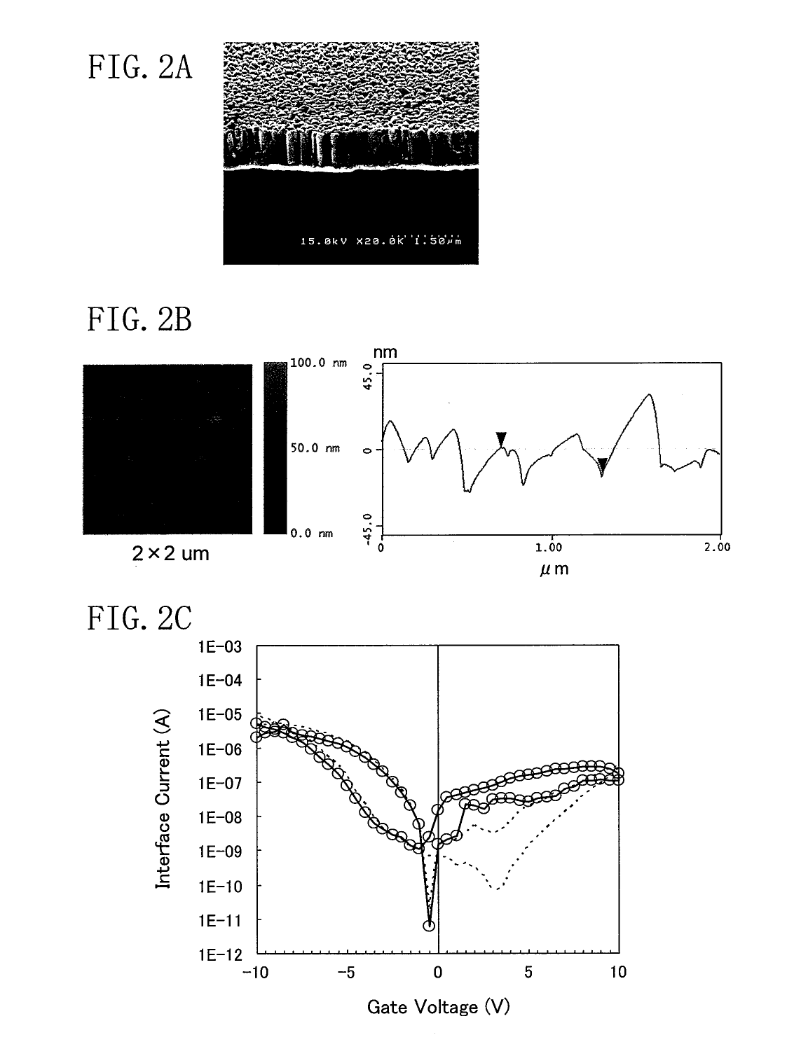

FIG. 2A is an SEM image of the PZT film 103 provided on the SiO₂ film 101b. The PZT film 103 is a (111) oriented polycrystalline film whose surface roughness is great as shown in FIG. 2B, that is, about 10 nm to 12 nm in RMS values. FIG. 2C is a graph showing a measurement result of an interface current (Ids-Vg properties) flowing between source and drain electrodes when a gate voltage is applied. The result is that a gate leakage current was large and only small current flowed in the interface. Accordingly there was no ON/OFF operation. This may be because the surface asperities of the PZT film 103 were so great that an electric field was concentrated at a recess when the gate voltage was applied, which resulted in an increase in gate leakage current, and also because the asperities were so great that carriers traveling along the interface were scattered greatly, which resulted in deterioration of the carrier mobility.

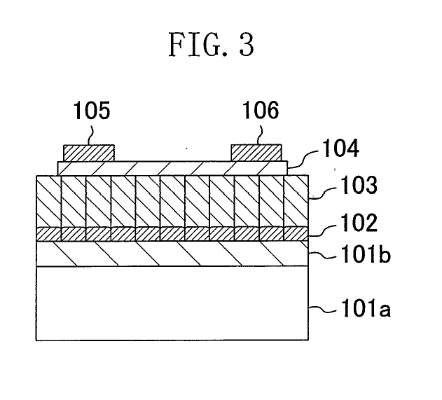

To prevent the electric field from concentrating at a recess, MFSFET was formed, as shown in FIG. 3, by planarizing the surface of the PZT film 103 by CMP (Chemical Mechanical Polishing) and then forming the semiconductor film 104 on the PZT film 103.

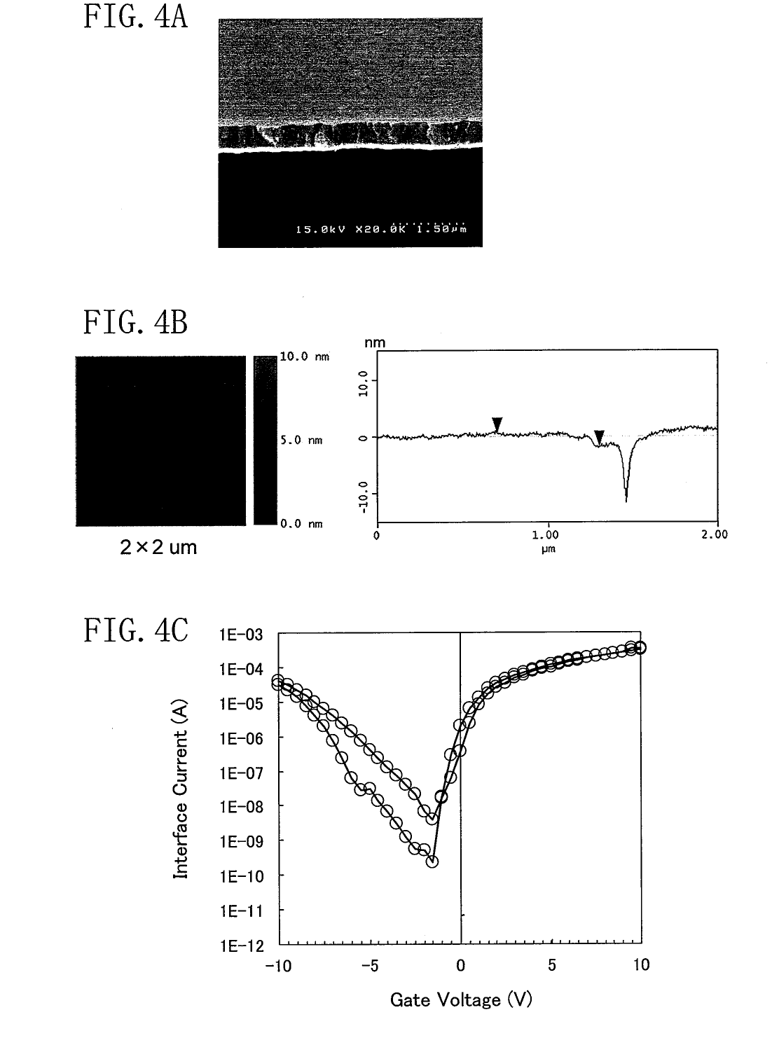

FIG. 4A is a SEM image of the polished PZT film 103. The surface of the PZT film 103 is planarized so that the surface roughness of the PZT film 103 is about 0.5 nm to 0.7 nm in RMS values, which is very smooth, as shown in FIG. 4B. The PZT film 103 is as planar as a PZT film obtained by an epitaxial growth method. FIG. 4C is a graph showing a measurement result of an interface current (Ids-Vg properties) flowing between source and drain electrodes when a gate voltage is applied. The result is that gate leakage current was reduced by an order of magnitude or more and ON/OFF modulation was observed. However, a memory window was closed and it was impossible to obtain the ON-OFF ratio at gate zero bias. The retaining characteristics were therefore not measured.

The inventors of the present invention concluded that the reason why the memory window was closed in spite of the fact that the surface of the PZT film 103 was polished to be as planar as a PZT film obtained by an epitaxial growth method, was that polishing causes damage, such as a crystal defect, on the surface of the PZT film 103 and the damage serves as a carrier trap level. In other words, if carriers are trapped during the application of the gate voltage, it shifts a threshold voltage of the MFSFET, and as a result, the memory window is closed.

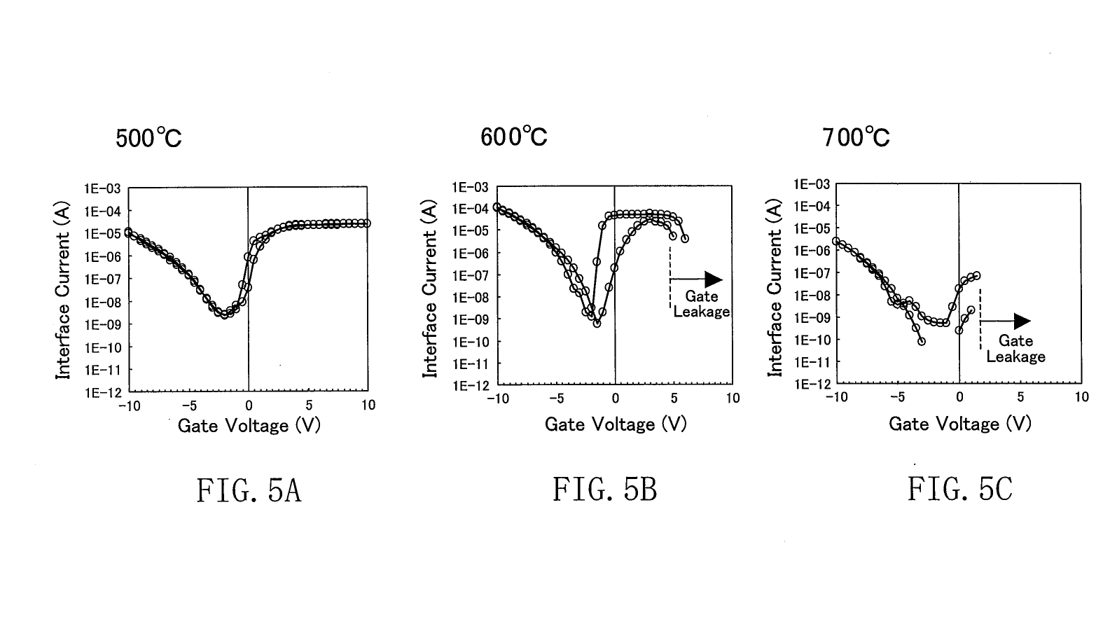

Although the inventors of the present invention attempted a heat treatment of the polished PZT film 103 in order to reduce crystal defects on the surface of the PZT film 103 which were caused by the polishing, no improvement in the memory window was found. FIG. 5A to FIG. 5C are graphs showing measurement results of an interface current when the polished PZT film 103 is subjected to a heat treatment. No improvement was made by the heat treatment at 500° C., and generation of gate leakage current was found in the heat treatment at 600° C. or higher. This may be because a heat treatment at low temperatures cannot sufficiently reduce crystal defects that may generate an interface level and because in a heat treatment at high temperatures, a constituent element of the PZT film 103, such as lead, starts to diffuse, which deteriorates film quality and makes the gate leakage current dominant.

The present invention was made based on the above findings and an object of the present invention is to provide a ferroelectric film having excellent interface properties and provide a field effect transistor or a ferroelectric capacitor in which a ferroelectric film having the above interface properties is used and which have excellent electric characteristics.

Embodiments of the present invention are hereinafter described with reference to the drawings. In the following drawings, structural elements having substantially the same function are labeled with the same reference numeral for the sake of brevity of description. The present disclosure relates to a ferroelectric stacked-layer structure including a planarized first ferroelectric film and a second ferroelectric film with no crystal defect on the surface. In the following embodiments, the device in which the ferroelectric stacked-layer structure is applied to a gate insulating film or a capacitor film is described as an example. The present invention is not limited to the following embodiments.

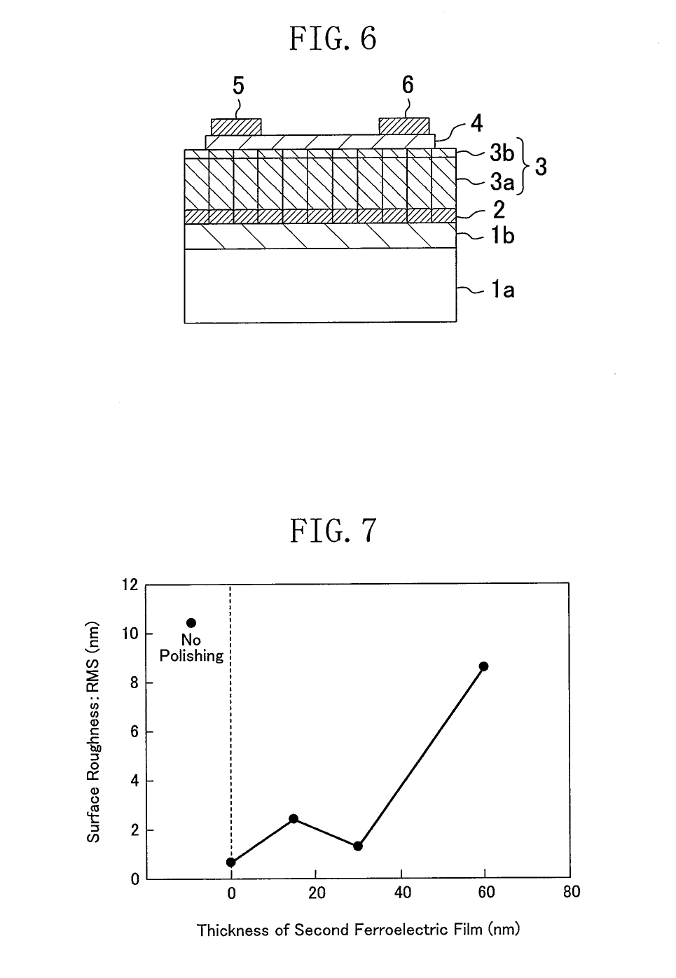

FIG. 6 is a schematic cross section of the structure of a field effect transistor according to the first embodiment of the present invention.

As shown in FIG. 6, a field effect transistor according to the present embodiment includes a gate insulating film 3 composed of a ferroelectric stacked-layer structure, 3a and 3b. The basic structure of the field effect transistor is the same as that of the structure shown in FIG. 1.

The ferroelectric stacked-layer structure includes a first polycrystalline ferroelectric film 3a and a second thin ferroelectric film 3b formed on the first ferroelectric film 3a. The first ferroelectric film 3a has a planarized surface, and the second ferroelectric film 3b has the same crystalline structure as that of the first ferroelectric film 3a.

The concrete structure of the field effect transistor according to the present embodiment is hereinafter described.

As shown in FIG. 6, a silicon oxide film 1b is provided on a silicon substrate 1a. A gate electrode 2 composed of a multilayered film of strontium ruthenium oxide (SrRuO₃: SRO)/platinum (Pt) is provided on the silicon oxide film 1b, with a titanium (Ti) adhesion layer interposed therebetween. Since the gate electrode 2 has a polycrystalline structure, the surface roughness of the gate electrode 2 is great, 5 nm or more in RMS values.

A first polycrystalline ferroelectric film 3a of PZT is provided on the gate electrode 2. The surface of the first ferroelectric film 3a is planarized so that the surface roughness is about 0.5 nm to 0.7 nm in RMS values. A second thin ferroelectric film 3b (about 15 nm to 40 nm in thickness, for example) formed of PZT is provided on the first ferroelectric film 3a. These first and second ferroelectric films 3a and 3b constitute the ferroelectric stacked-layer structure 3. Provided on the ferroelectric stacked-layer structure 3 is a semiconductor film 4 of ZnO, on which a source electrode 5 and a drain electrode 6 composed of an SRO/Pt multilayered film are further provided.

According to the present embodiment, the second ferroelectric film 3b, provided on the planarized first ferroelectric film 3a, has a planar surface, and because the crystal defect generated on the surface of the first ferroelectric film 3a by the planarization is not exposed on the surface, excellent interface properties with a reduced carrier trap level are obtained. It is therefore possible to achieve a field effect transistor with a reduced leakage current, no threshold voltage shift, and excellent ON-OFF ratio and retaining characteristics.

In the present embodiment, the material for the first and second ferroelectric films 3a and 3b which constitute a ferroelectric stacked-layer structure 3 is not limited to any specific material as long as the first and second ferroelectric films 3a and 3b have the same crystalline structure. For example, other than a PZT film, a material, such as bismuth titanate (Bi₄Ti₃O₁₂), bismuth lanthanum titanate (Bi_{3.25}La_{0.75}Ti₃O₁₂), strontium bismuth tantalate (Sr(Bi, Ta)₂O₉), bismuth ferrite (BiFeO₃), and yttrium manganite (YMnO₃) may be used for the ferroelectric films.

It is preferable that the crystal orientation of the first ferroelectric film 3a and the crystal orientation of the second ferroelectric film 3b are aligned. With the ferroelectric stacked-layer structure 3 in which crystal orientations are aligned being utilized in the field effect transistor, variations in polarization between the field effect transistors are reduced to a very low level even if the field effect transistors are microfabricated. Variations in ON/OFF current are accordingly reduced. If the ferroelectric films are made of a material having a perovskite structure, it is easier to align the orientation of the ferroelectric films with the orientation of Pt, Ir, and SRO used for the electrodes.

The first ferroelectric film 3a and the second ferroelectric film 3b do not necessarily have to be made of materials having the same constituent elements, but may be made of materials whose constituent elements are different in part from each other. This makes it possible to control the barrier height of the ferroelectric film relative to a conductive film, a semiconductor film, or an insulating film and to reduce leakage current through the ferroelectric film. It is also possible to control the reaction and mutual diffusion between the ferroelectric film and a conductive film, a semiconductor film, or an insulating film, and thus reduce a carrier trap level at the interface.

Further, when the ferroelectric film is made of PZT, the PZT may be doped with elements, such as lanthanum (La), niobium (Nb), vanadium (V), tungsten (W), praseodymium (Pr), and samarium (Sm). The crystallization temperature is decreased by the doping of a different element. As a result, the ferroelectric film can be formed at low temperatures and fatigue from repeated polarization reversal can be reduced.

It is preferable that the thickness of the second ferroelectric film 3b is in a range of 1 nm to 60 nm. With the thickness of 1 nm or less, the second ferroelectric film 3b cannot completely cover the surface asperities of the first ferroelectric film 3a. If the thickness of the second ferroelectric film 3b is 60 nm or more, the surface roughness of the second ferroelectric film 3b is substantially equal to the surface roughness without polishing as shown in FIG. 7.

The ferroelectric stacked-layer structure of the present invention carries out a single function. For example, in the case where a single-layered ferroelectric film used as part of structural element of a device is replaced with the ferroelectric stacked-layer structure of the present invention, the ferroelectric stacked-layer structure of the present invention carries out the same function which the single-layered ferroelectric film of the device may carry out.

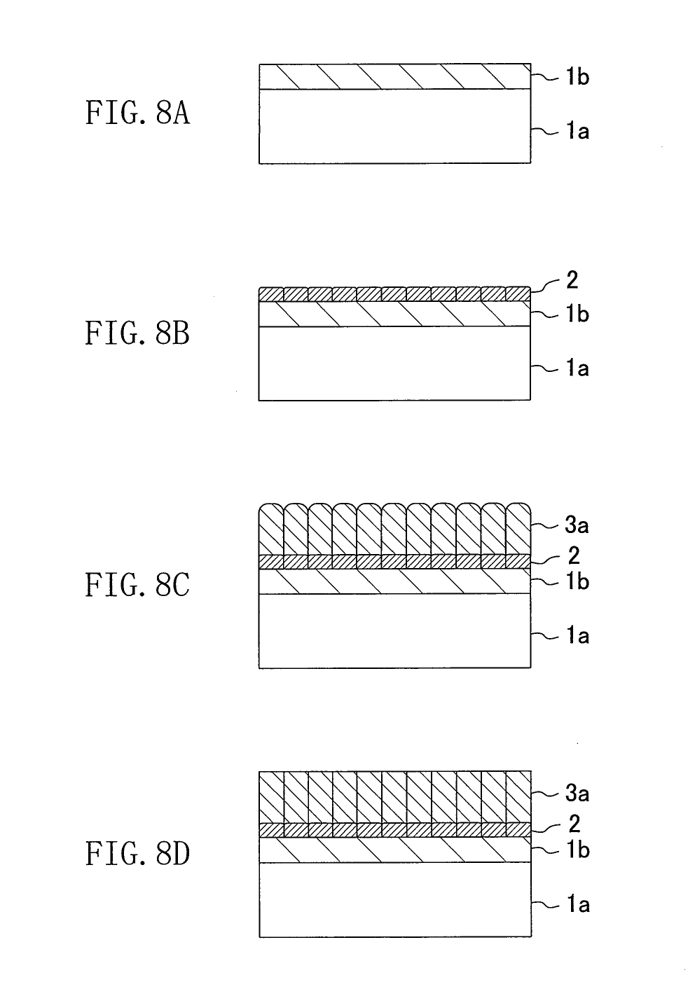

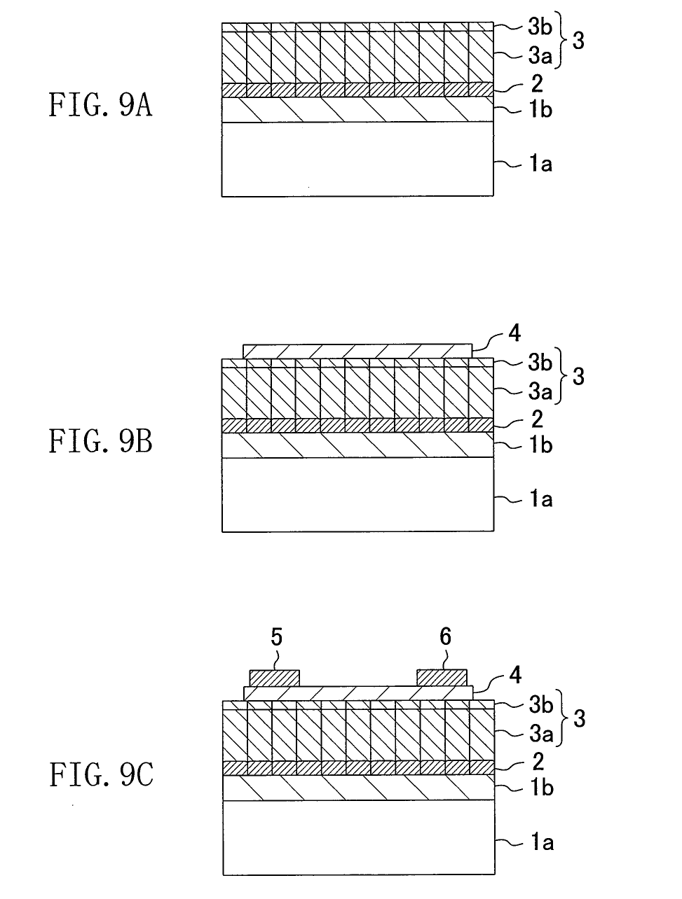

A fabrication method of the field effect transistor according to the present embodiment is hereinafter described with reference to the cross sections of FIG. 8A to FIG. 9C.

As shown in FIG. 8A, an SiO₂ film 1b having a thickness of about 500 nm is formed by plasma CVD on the surface of an Si substrate 1a cut along a (100) plane.

Then, as shown in FIG. 8B, the substrate is heated to 200° C. and a Ti film having a thickness of about 30 nm and a Pt film having a thickness of about 200 nm are formed by sputtering on the SiO₂ film 1b. After that, the substrate is heated to 700° C. and an SRO film having a thickness of about 30 nm is deposited by Pulsed Laser Deposition (PLD) under the oxygen partial pressure of 10 mTorr to obtain a gate electrode 2.

Next, as shown in FIG. 8C, a first ferroelectric film 3a made of PZT and having a thickness of about 850 nm is formed on the gate electrode 2 by PLD under the oxygen partial pressure of 100 mTorr, with the substrate heated to 700° C.

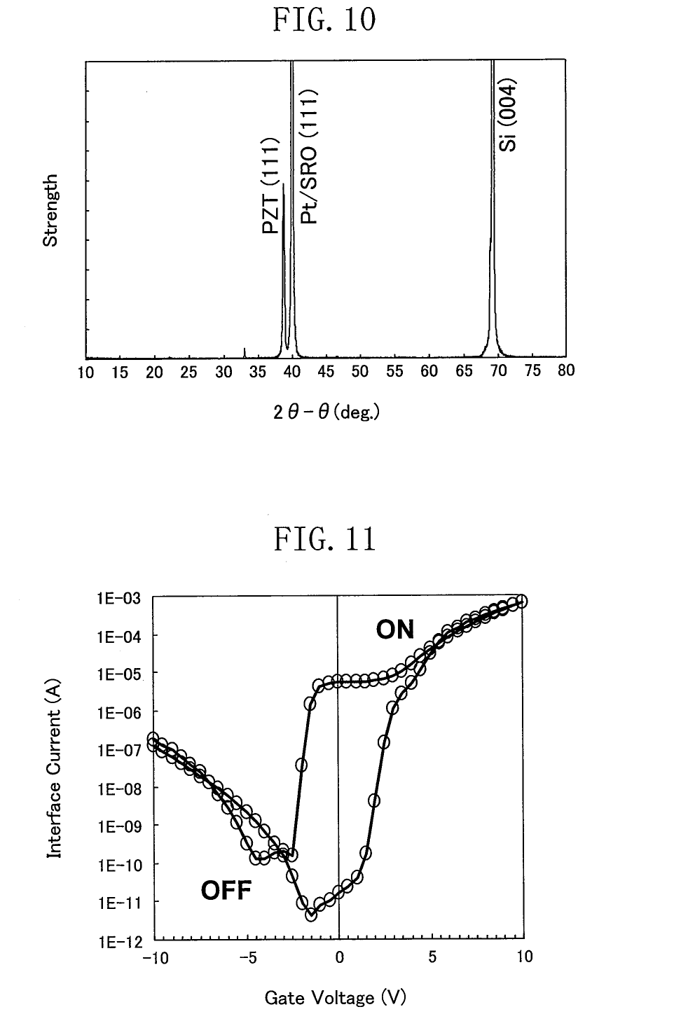

Herein, the composition of the sintered material used as a target of PLD is Pb:Zr:Ti=1:0.30:0.70. The reason why an SRO film is formed as an uppermost layer of the gate electrode 2 is that the use of a conductive oxide as a layer coming in contact with the PZT film 3a may suppress deterioration of the PZT film 3a because of fatigue from polarization reversal. Further, the relationship among the lattice constants of the Pt, SRO and PZT films are approximately 3.91 Å (Pt film)<3.93 Å (SRO film)<4.04 Å (PZT film), which reveals that the differences among the lattice constants is smaller when the PZT film is formed on the Pt film with the SRO film interposed therebetween, than when the PZT film is formed directly on the Pt film. It is therefore possible to obtain the PZT film 3a with excellent crystallinity. In fact, the PZT film 3a formed on the SRO film is completely (111) oriented as can be seen from the result of an X-ray diffraction in FIG. 10. Crystals in the same orientation have an equal polarization amount with each other. Therefore, with the PZT film 3a in which orientations are aligned being utilized in a field effect transistor, variations in polarization between the field effect transistors are reduced to a very low level even if the field effect transistors are microfabricated. Variations in ON/OFF current are accordingly reduced. The surface roughness of the PZT film 3a is about 8 nm to 12 nm in RMS values.

Then, the surface of the PZT film 3a is planarized as shown in FIG. 8D. Specifically, the surface of the PZT film 3a is polished by Chemical Mechanical Polishing (CMP) by using slurry in which colloidal silica (particle size of 40 nm) is mixed into a strong alkaline solution of potassium hydroxide whose pH value is adjusted to pH 10, and applying a load so that the polishing rate is 90 nm/min for about five minutes until the thickness of the PZT film 3a is about 400 nm. After polishing, the surface roughness of the PZT film 3a is 0.6 nm or less in RMS values. The figure is smaller than the figure for the surface roughness of a PZT film that is obtained when the PZT film and an SRO film are hetero-epitaxially grown on an STO substrate whose surface is planarized. The surface asperities of the polycrystalline PZT film 3a are almost completely removed.

Next, as shown in FIG. 9A, the substrate is heated again to 700° C., and a PZT film 3b having a thickness of about 30 nm is formed on the PZT film 3a by PLD under the oxygen partial pressure of 100 mTorr and the same conditions as when the PZT film 3a is formed. The surface roughness of the PZT film 3b is about 1.0 nm to 1.5 nm in RMS values. The figure is almost equal to the figure for the planarized surface of a hetero-eptaxially grown PZT film.

Next, as shown in FIG. 9B, a ZnO film 4 which has a thickness of about 30 nm and of which carriers are n-type is formed by PLD, with the substrate heated to 400° C. With the thickness of about 30 nm, the ZnO film 4 is formed without deterioration of crystallinity and thus, it is possible to lower carrier concentration. The film with low carrier concentration has an intrinsically high resistance value, and thus OFF current is reduced in the transistor operation. It is therefore anticipated that high ON-OFF ratio may be obtained.

Next, as shown in FIG. 9C, the ZnO film 4 in the region other than the device region is removed by etching and then a source electrode 5 and a drain electrode 6 which are composed of a multilayered film of Ti (having a thickness of about 30 nm)/Pt (having a thickness of about 60 nm) are formed on the ZnO film 4 by lift-off.

Herein, the ZnO film 4 may be doped with an element, such as magnesium (Mg), gallium (Ga), and aluminum (Al). By doing so, bandgap and carrier concentration are freely adjusted and the switching state may be controlled. Further, the ZnO film may be replaced with an amorphous oxide semiconductor (In—Ga—Zn—O, Sn—Ga—Zn—O) composed of tin dioxide (SnO₂), indium tin oxide (ITO), tin, indium, gallium, zinc, and oxygen. Furthermore, the SRO film 2, the PZT films 3a and 3b, and the ZnO film 4 may be deposited not only by PLD but also by the methods such as Metal-Organic Chemical Vapor Deposition (MOCVD), sputtering, and Molecular Beam Epitaxy (MBE).

FIG. 11 is a graph showing the interface current properties (Ids-Vg properties) of an field effect transistor according to the present embodiment and indicates values of a drain current Id (interface current) relative to a gate voltage Vg when the source electrode 5 is grounded and a 0.1 V drain voltage Vd is applied. The drain current exhibits different loci (hysteresises) between when the scan sequence of the gate voltage Vg is from −10 V to +10 V and when it is from +10 V to −10 V. The respective drain currents where Vg=0 V is 100 pA or less and 1 μA or more, which means that the current ratio of four digits or more is obtained.

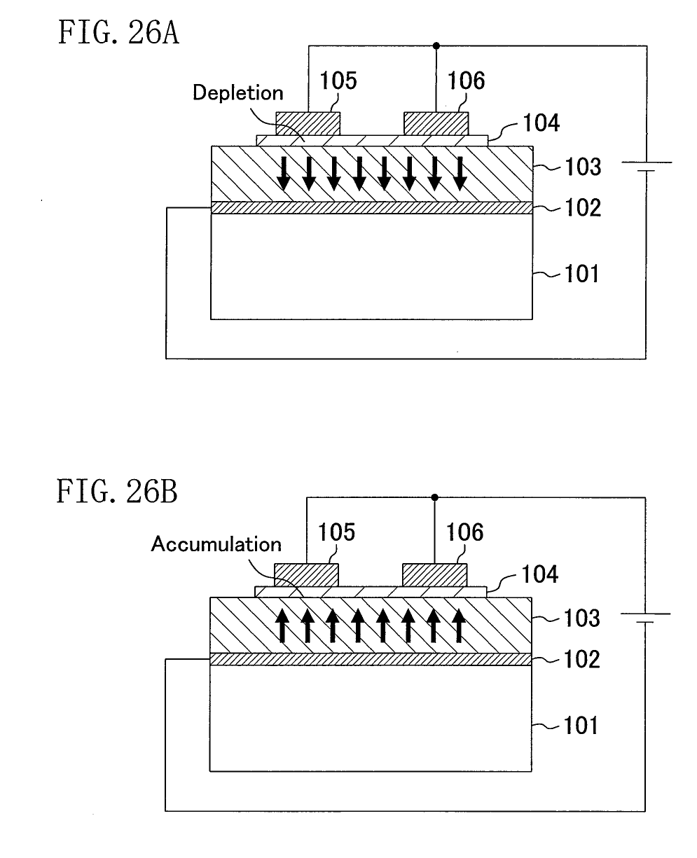

The reason why the current values differ from each other even when the gate voltage Vg is OFF is that the depletion/accumulation of interface charge is retained because of remnant polarization of the PZT film 3 (ferroelectric film). Specifically, as shown in FIG. 26A, polarization of the PZT film 3 is oriented downward when a negative voltage is applied to the gate electrode 2. Carriers are swept away due to the polarization, and depletion occurs in the entire ZnO film 4 (channel). As a result, the ZnO film 4 is in a high resistance state (OFF state). On the other hand, as shown in FIG. 26B, polarization of the PZT film 3 is oriented upward when a positive voltage is applied to the gate electrode 2. Carriers in the density corresponding to the polarization density are induced at the interface and charge is accumulated. As a result, the ZnO film 4 is in a low resistance state (ON state).

The drain current (interface current), large or small, is made to correspond to binary data “1” or “0.” The field effect transistor can thus function as a memory device. Remnant polarization of the ferroelectric film is retained even when the voltage is OFF, which enables the structure to function as a nonvolatile memory.

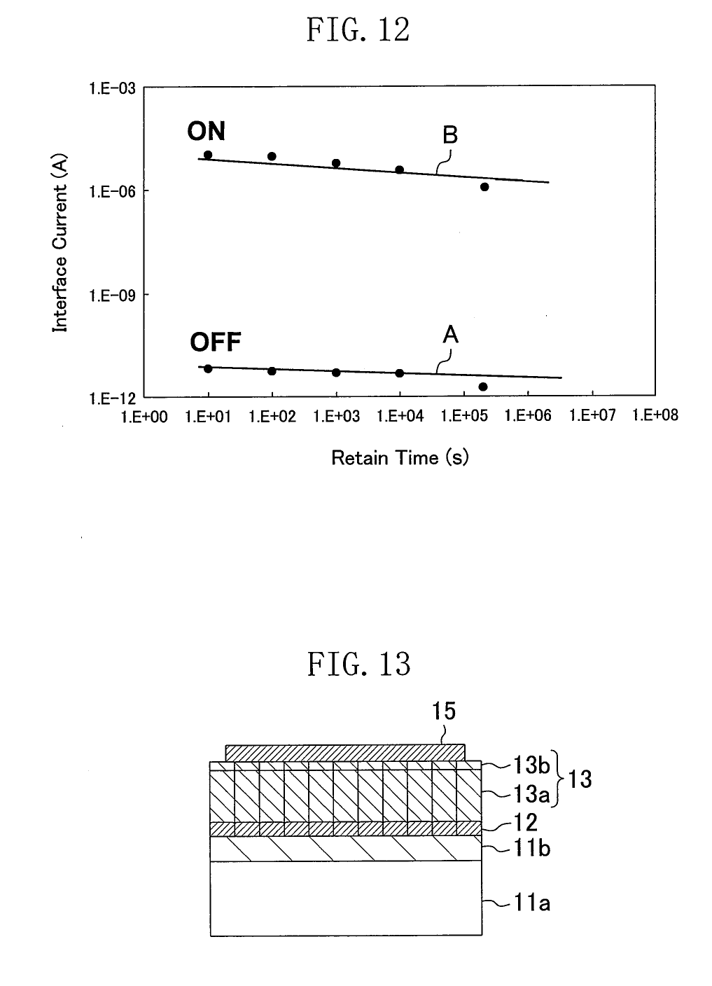

FIG. 12 is a graph showing a retaining time of ON-OFF ratio. Line A represents the state where the field effect transistor is OFF, and Line B represents the state where the field effect transistor is ON. The ON-OFF ratio is obtained by measuring the drain current of the time when +10 V and −10 V are respectively applied to the gate electrode and after that a 0.1 V drain voltage is applied with a 0 V gate voltage. As can be seen from FIG. 12, the ON-OFF ratio of four digits or more is retained even after the device is set aside for ten to the fifth power seconds at room temperatures. This retaining characteristic is at the equal level of the retaining characteristic of the device in which a ferroelectric is planarized by epitaxial growth.

FIG. 13 is a schematic cross section of the structure of a ferroelectric capacitor according to the second embodiment of the present invention, wherein a capacitor film 13 is composed of a ferroelectric stacked-layer structure, 13a and 13b.

The ferroelectric stacked-layer structure is composed of a first polycrystalline ferroelectric film 13a and a second thin ferroelectric film 13b stacked on the first ferroelectric film 13a. The first ferroelectric film 13a has a planarized surface, and the second ferroelectric film 13b has the same crystalline structure as that of the first ferroelectric film 13a.

The concrete structure of the ferroelectric capacitor according to the present embodiment is hereinafter described. Elements of the ferroelectric capacitor other than a lower electrode 12 and an upper electrode 15 are basically the same as the elements of the field effect transistor shown in FIG. 6. The detailed description of the identical elements is omitted.

As shown in FIG. 13, a lower electrode 12 composed of a multilayered film of Ti/Pt/SRO is provided on an Si substrate 11a which has an SiO₂ film 11b on the top surface. A first polycrystalline ferroelectric film 13a of PZT is provided on the lower electrode 12. The surface of the first ferroelectric film 13a is planarized so that the surface roughness is approximately 0.5 nm to 0.7 nm in RMS values. A second thin ferroelectric film 13b (about 15 nm to 40 nm in thickness, for example) formed of PZT is provided on the first ferroelectric film 13a. These first and second ferroelectric films 13a and 13b constitute the ferroelectric stacked-layer structure 13. An upper electrode 15 composed of a multilayered film of STO/Pt is provided on the ferroelectric stacked-layer structure 13.

According to the present embodiment, the second ferroelectric film 13b, provided on the planarized first ferroelectric film 13a, has a planar surface, and because the crystal defect generated on the surface of the first ferroelectric film 13a by the planarization is not exposed on the surface, excellent interface properties with a reduced carrier trap level are obtained. It is therefore possible to achieve a ferroelectric capacitor with excellent characteristics, that is, a reduced leakage current and no deterioration due to fatigue from polarization reversal.

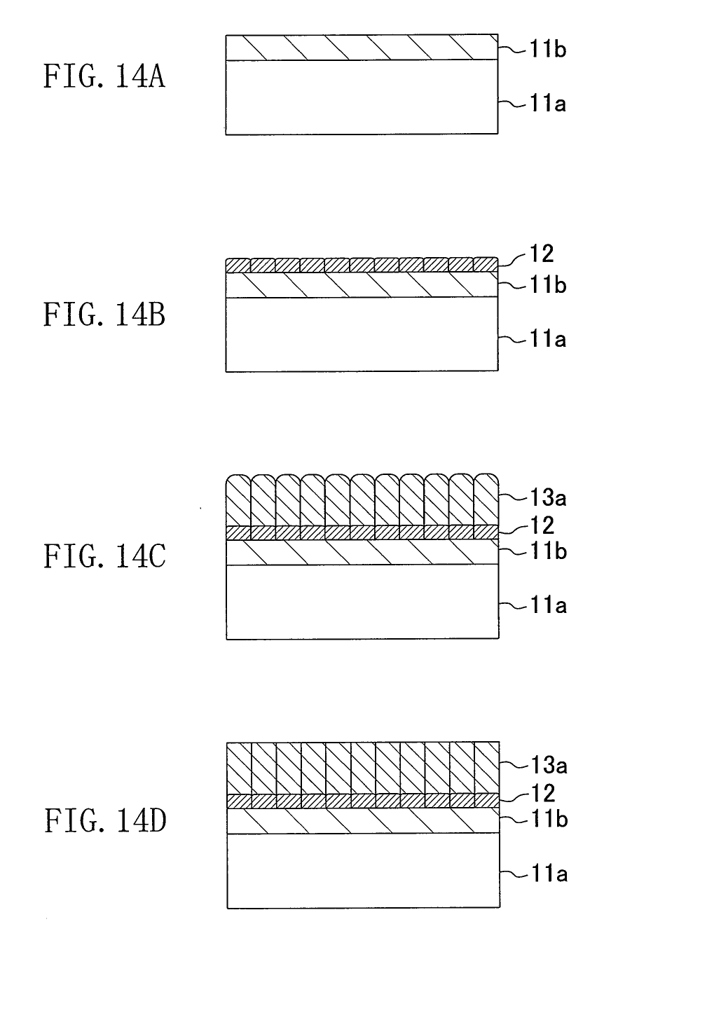

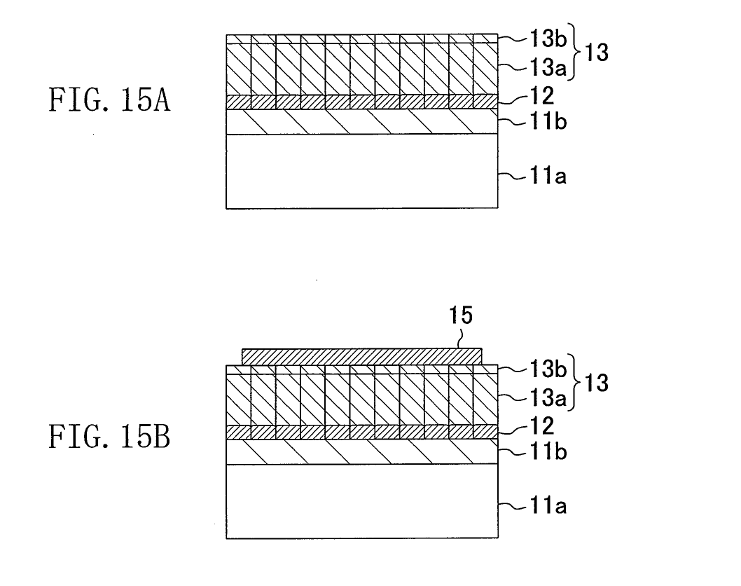

A fabrication method of the ferroelectric capacitor according to the present embodiment is hereinafter described with reference to the cross sections of FIG. 14A to FIG. 15B. Detailed description of the steps which are identical with the steps of the fabrication method of the field effect transistor shown in FIG. 8A to FIG. 9C is omitted.

As shown in FIG. 14A, an SiO₂ film 11b having a thickness of about 500 nm is formed on the surface of an Si substrate 11a cut along a (100) plane.

Then, as shown in FIG. 14B, a Ti (having a thickness of about 30 nm)/Pt (having a thickness of about 200 nm) film is formed on the SiO₂ film 11b by sputtering. After that an SRO film (having a thickness of about 30 nm) is deposited by PLD to form a gate electrode 12.

Next, as shown in FIG. 14C, a first ferroelectric film 13a of PZT having a thickness of about 850 nm is formed on the gate electrode 12 by PLD. Herein, the composition of the sintered material used as a target of PLD is Pb:Zr:Ti=1:0.30:0.70. Further, the PZT film 13a formed on the SRO film is completely (111) oriented. Therefore variations in polarization between ferroelectric capacitors are greatly reduced even if the ferroelectric capacitors are microfabricated. The surface roughness of the PZT film 13a is about 8 nm to 12 nm in RMS values.

Then, the surface of the PZT film 13a is planarized by CMP as shown in FIG. 14D. The thickness of the polished PZT film 13a is about 400 nm, and the surface roughness is 0.6 nm or less in RMS values.

Next, as shown in FIG. 15A, a PZT film 13b having a thickness of about 30 nm is formed on the PZT film 13a by PLD under the same conditions when the PZT film 13a is formed. The surface roughness of the PZT film 13b is about 1.0 nm to 1.5 nm in RMS values.

Next, as shown in FIG. 15B, an upper electrode 15 composed of a Pt film (having a thickness of about 100 nm) is formed on the PZT film 13b by an electron beam vapor deposition method using a shadow mask pattern.

Herein, the PZT films 13a and 13b may be doped with an element, such as lanthanum (La), niobium (Nb), vanadium (V), tungsten (W), praseodymium (Pr), and samarium (Sm). The crystallization temperature is decreased by the doping of a different element. As a result, the films can be formed at low temperatures and fatigue from repeated polarization reversal can be reduced. Further, the PZT films may be replaced with a ferroelectric film formed of such as bismuth titanate (Bi₄Ti₃O₁₂), bismuth lanthanum titanate (Bi_{3.25}La_{0.75}Ti₃O₁₂), strontium bismuth tantalate (Sr(Bi, Ta)₂O₉), bismuth ferrite (BiFeO₃), and yttrium manganite (YMnO₃).

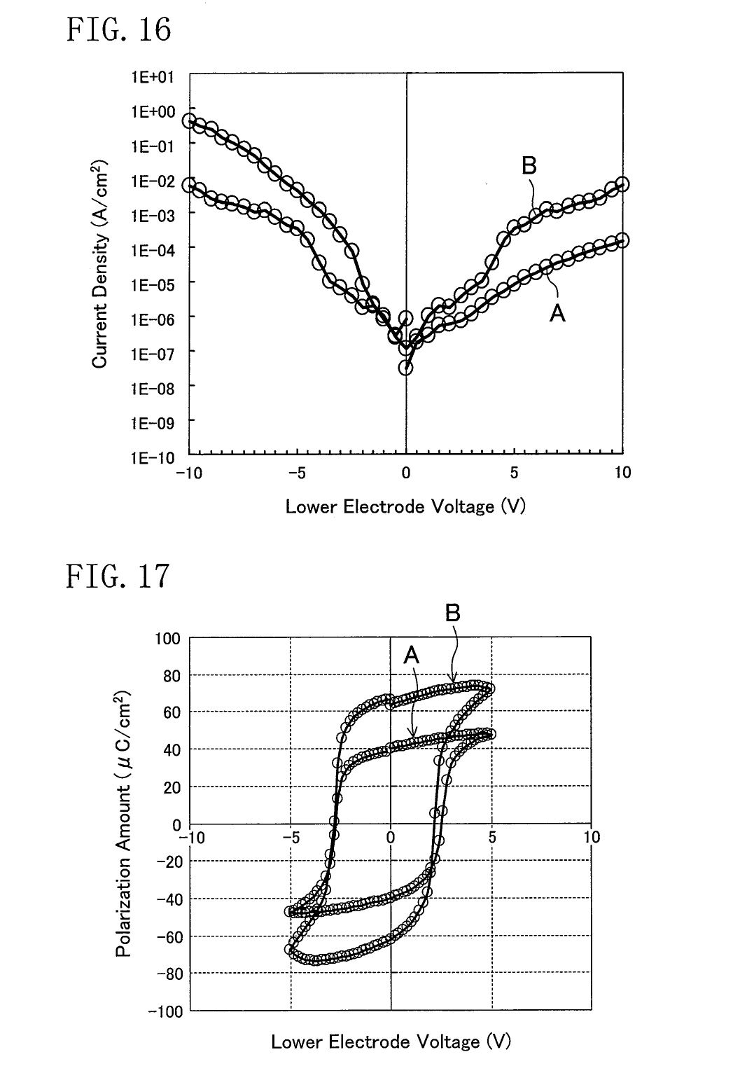

FIG. 16 is a graph showing the current-voltage properties of the ferroelectric capacitor according to the present embodiment. Line A represents the properties of the ferroelectric capacitor according to the present embodiment and Line B represents, for comparison, the properties of a ferroelectric capacitor of a single layered PZT which has a thickness of 450 nm and of which a surface is not planarized. The leakage current of the ferroelectric capacitor according to the present embodiment is reduced by about an order of magnitude, compared to the leakage current of the conventional one. This is because asperities at the interface between the PZT film 13b having a planarized surface and the upper electrode 15 are reduced and the electric field concentration are lowered.

FIG. 17 is a graph showing the polarization-voltage properties of the ferroelectric capacitor according to the present embodiment. Line A represents the properties of the ferroelectric capacitor according to the present embodiment and Line B represents, for comparison, the properties of a ferroelectric capacitor of a single layered PZT which has a thickness of 450 nm and of which the surface is not planarized. The ferroelectric capacitor according to the present embodiment exhibits a hysteresis curve which spreads less at the higher voltage side and has better rectangular characteristics than the hysteresis curve of the conventional one. This reveals that the interface state between the PZT film 13b and the upper electrode 15 are excellent and leakage current is reduced in the ferroelectric capacitor according to the present embodiment.

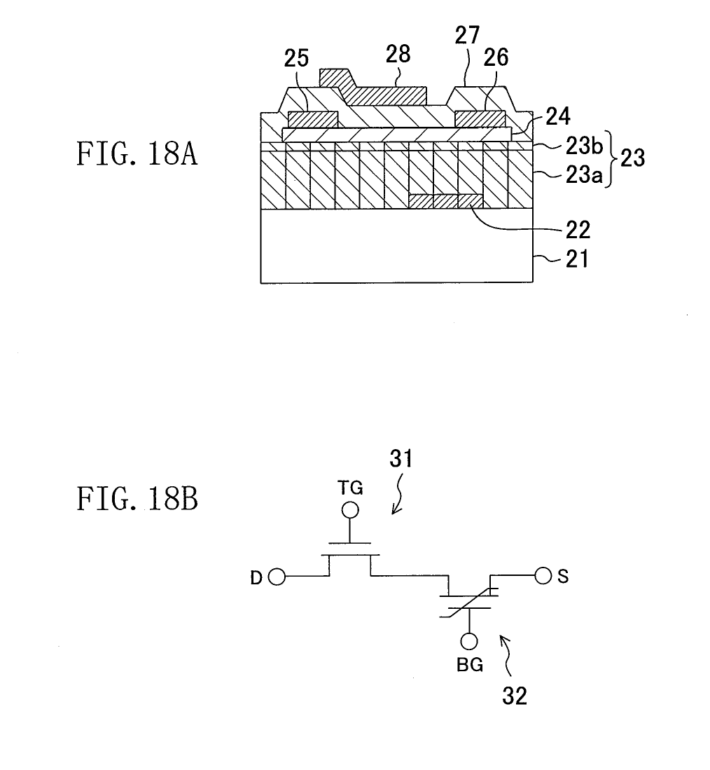

FIG. 18A is a schematic cross section of the structure of a semiconductor memory device according to the third embodiment of the present invention. FIG. 18B is an equivalent circuit of the semiconductor memory device. The semiconductor memory device according to the present embodiment has the structure in which the field effect transistor 31 of the first embodiment is used as a memory cell to which a switching element 32 is connected.

The concrete structure of the semiconductor memory device according to the present embodiment is hereinafter described. Elements of the field effect transistor 31 are basically the same as the elements of the field effect transistor shown in FIG. 6. The detailed description of the identical elements is omitted.

As shown in FIG. 18A, a first gate electrode 22 composed of a zinc-doped indium tin oxide (ZITO) film having a thickness of 30 nm is provided on a quartz substrate 21. A PZT film 23 (ferroelectric film) having a thickness of 400 nm overlies the quartz substrate 21 so as to cover the first gate electrode 22. The PZT film 23 is composed of a first polycrystalline ferroelectric film 23a and a second thin ferroelectric film 23b formed on the first ferroelectric film 23a. The first ferroelectric film 23a has a planarized surface, and the second ferroelectric film 23b has the same crystalline structure as that of the first ferroelectric film 23a.

An n-type ZnO film 24 (semiconductor film) having a thickness of 30 nm is provided on the PZT film 23. A source electrode 25 and a drain electrode 26 which are composed of an ITO film having a thickness of 60 nm are provided on the ZnO film 24. A silicon nitride (SiNx) film 27 (paraelectric film) having a thickness of 50 nm overlies the ZnO film 24 so as to cover the source electrode 25 and the drain electrode 26. A second gate electrode 28 composed of a ZITO film having a thickness of 60 nm is provided on the SiNx film 27.

The semiconductor memory device according to the present embodiment is composed of a bottom gate type MFSFET 31 including the first gate electrode 22, the ferroelectric gate insulating film formed of the PZT film 23, and the ZnO film 24 as a channel, and a top gate type MISFET 32 including a second gate electrode 28, a paraelectric gate insulating film formed of the SiNx film 27, and the ZnO film 24 as a channel, as shown in FIG. 18B. The MFSFET 31 and the MISFET 32 are connected in series, sharing the same channel. The source electrode 25 and the drain electrode 26 sandwich the two FETs arranged next to each other.

All elements of the semiconductor memory device according to the present embodiment, including the substrate 21, are formed of a transparent oxide having 90% or more transmittance to visible light. Hence, it is possible to add memory and switching functions to an object which requires transparency, such as electronic paper, if the present semiconductor memory device is utilized in the object.

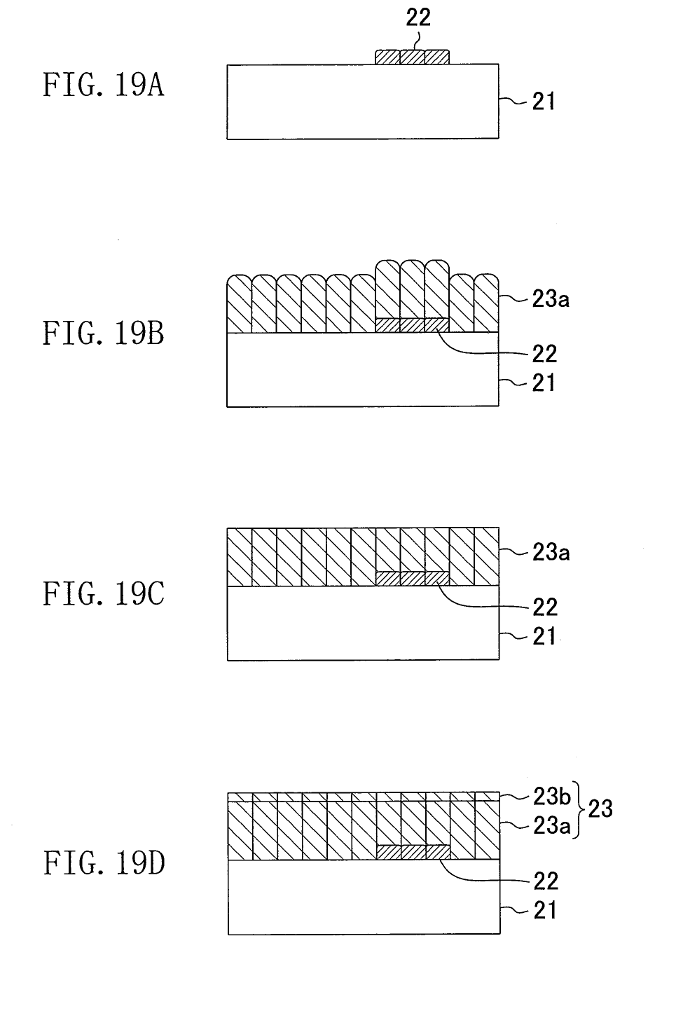

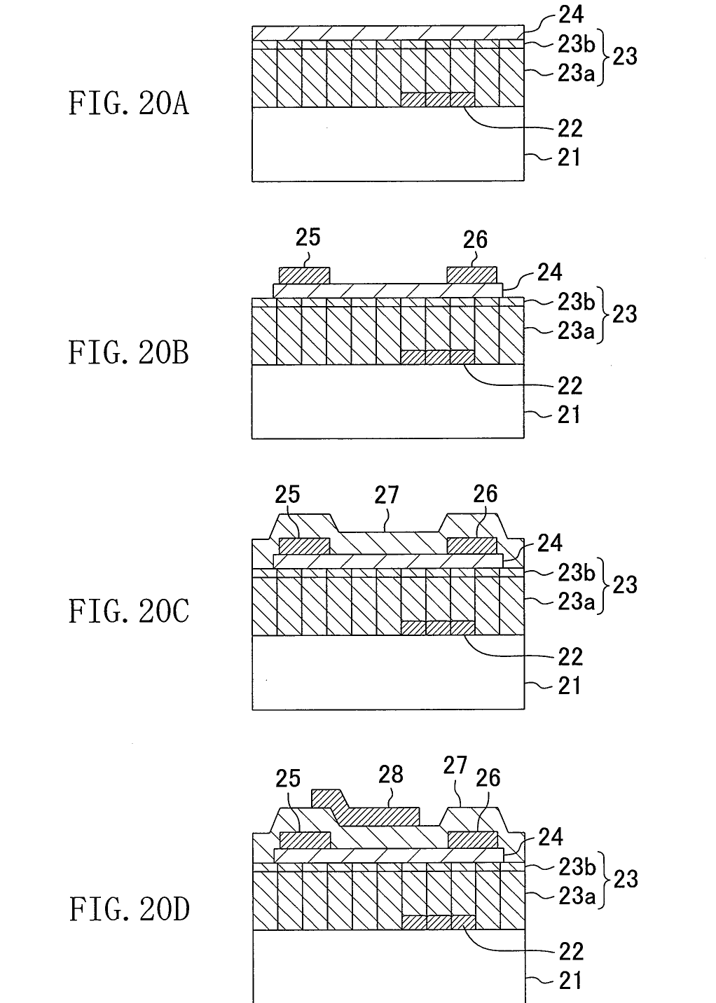

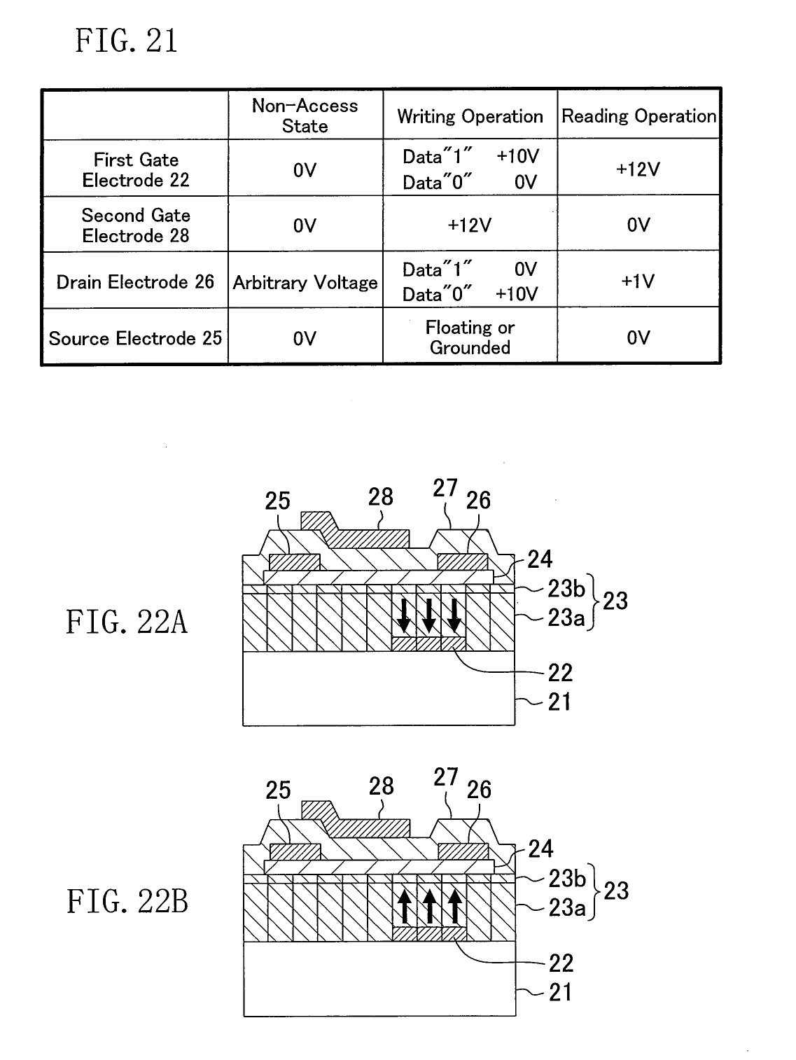

A fabrication method of the semiconductor memory device according to the present embodiment is hereinafter described with reference to the cross sections of FIG. 19A to FIG. 20D. Detailed description of the steps which are similar to the steps in the fabrication method of the field effect transistor shown in FIG. 8A to FIG. 9C is omitted.

First, a patterned resist (not shown) is formed on the quartz substrate 21, and then, a ZITO film having a thickness of 30 nm is formed by PLD under the oxygen partial pressure of 10 mTorr, with the substrate kept at room temperatures. After that, the resist is removed by lift-off to form the first gate electrode 22.

Then, the first gate electrode 22 is subjected to a heat treatment in an oxygen atmosphere at 1 atmospheric pressure. After that, the PZT film 23a having a thickness of 500 nm is formed, with the substrate surface kept at 700° C. The composition of the sintered material used as a target is Pb:Zr:Ti=1:0.52:0.48. The ferroelectric gate insulating film formed of the PZT film 23a having this composition ratio reduces leakage current.

Next, as shown in FIG. 19C, the surface of the PZT film 23a is planarized by CMP. The thickness of the polished PZT film 23a is about 200 nm.

Next, as shown in FIG. 19D, the PZT film 23b having a thickness of about 30 nm is formed on the PZT film 23a by PLD under the same conditions when the PZT film 23a is formed.

Next, as shown in FIG. 20A, the ZnO film 24 having a thickness of 30 nm is formed by PLD, with the substrate kept at 400° C.

Next, as shown in FIG. 20B, the ZnO film 24 in the region other than the channel region is removed by etching, and then, the source electrode 25 and the drain electrode 26 composed of an ITO film having a thickness of 60 nm are formed on the ZnO film 24 by lift-off.

Then, as shown in FIG. 20C, the SiNx film 27 having a thickness of 50 nm is formed on the ZnO film 24 by sputtering.

Lastly, as shown in FIG. 20D, a second gate electrode 28 composed of a ZITO film having a thickness of 60 nm is formed on the SiNx film 27 by lift-off.

An operation of the semiconductor memory device according to the present embodiment is hereinafter described.

In the non-access state, the first gate electrode 22, the second gate electrode 28 and the source electrode 25 are grounded. MISFET 32 is OFF because the second gate electrode 28 is grounded. Therefore false writing to MISFET 32 does not occur even when an arbitrary voltage is applied to the drain electrode 26.

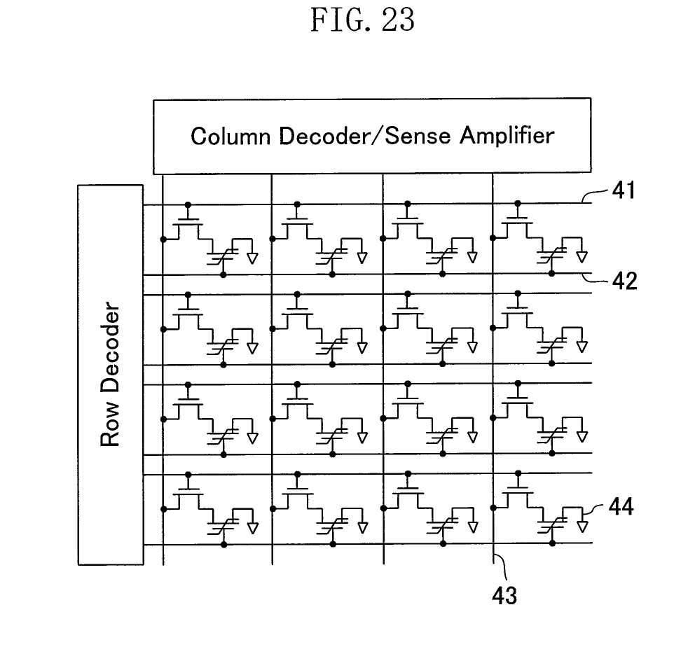

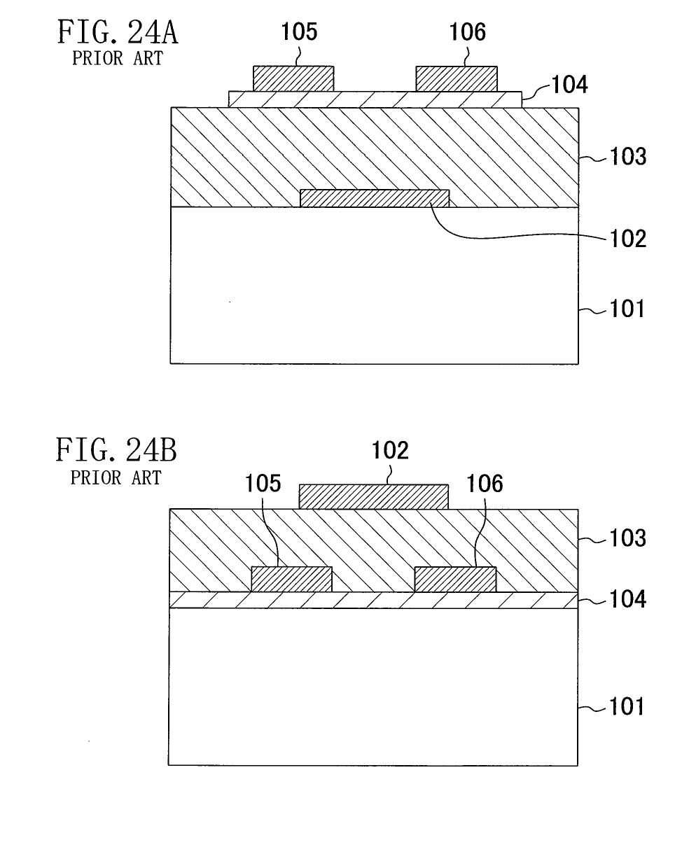

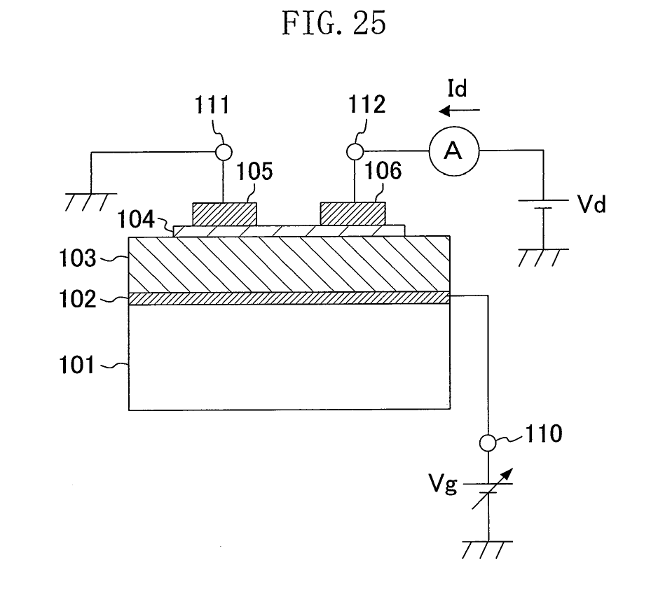

To conduct a data write operation, a positive voltage (12 V, for example) is applied to the second gate electrode 28 to turn on MISFET 32, and another voltage is applied to the drain electrode 26 and the first gate electrode 22 so that a write voltage is applied between the channel and the first gate electrode 22. Specifically, in the case of data “1”, the drain electrode 26 is grounded and a positive voltage (10 V, for example) is applied to the first gate electrode 22. In the case of data “0”, the first gate electrode 22 is grounded and a positive voltage (10 V, for example) is applied to the drain electrode 26. By doing so, the polarization of the PZT film 23 is oriented upward (toward the first gate electrode 22) in the case of data “0” as shown in FIG. 22A, and the polarization of the PZT film 23 is oriented downward (toward the channel 24) in the case of data “0” as shown in FIG. 22B.

To conduct a data read operation, the first gate electrode 22 is grounded; a positive voltage is applied to the second gate electrode 28 to turn on MISFET 32; and another voltage is applied between the drain electrode 26 and the source electrode 25. If the drain current is large, the data is “1.” If the drain current is small, the data is “0.”

The source electrode 25 may be floating or grounded during the write operation. In the former case, the polarization of the entire PZT film 23 on the first gate electrode 22 is reversed. In the latter case, the polarization of the PZT film 23 near the source electrode 25 is always oriented upward, irrespective of the application of a pulse. The channel 24 near the source electrode 25 is therefore always in the charge accumulation state (i.e., low resistance state) but there is no trouble in writing and reading data as long as the charge accumulation region has a short length along the channel length of MFSFET 31.

FIG. 23 shows a circuit diagram in which the semiconductor memory devices according to the present embodiment are arranged in a 4×4 array. The first gate electrode 22 of each semiconductor memory device is connected to a first word line 41 of the row decoder. The second gate electrode 28 is connected to the second word line 42. The drain electrode 26 is connected to a bit line 43 of the column decoder. The source electrode 25 is connected to a source line 44. The source electrode 25 and the drain electrode 26 can be shared between vertically adjacent two memory cells if the memory devices in the vertical direction are alternately turned upside-down. As a result, the area for a memory cell can be reduced.

While the present invention is described based on the above preferred embodiments, the invention is not limited to these descriptions of the embodiments, and of course, various variations are possible. For example, the ferroelectric stacked-layer structure of the present invention is not only applied to a field effect transistor or a ferroelectric capacitor as in the above embodiments, but can also be applied to a probe-type memory in which data is written and read by making a probe abut on a surface of a ferroelectric film.

What is claimed is:

1. A method for fabricating a ferroelectric stacked-layer structure, comprising:
(a) forming a first polycrystalline ferroelectric film on a polycrystalline or amorphous substrate;
(b) planarizing a surface of the first ferroelectric film;
(c) stacking on the planarized first ferroelectric film a second thin ferroelectric film having the same crystalline structure as the first ferroelectric film.

2. The method of claim 1, wherein a crystal orientation of the first ferroelectric film and a crystal orientation of the second ferroelectric film are aligned.

3. The method of claim 1, wherein the first ferroelectric film and the second ferroelectric film are formed of the same element.

4. The method of claim 1, wherein a thickness of the second ferroelectric film is in a range of 1 nm to 60 nm.

5. The method of claim 1, wherein the second ferroelectric film has a function of reducing a carrier trap level generated by a crystal defect on the planarized surface of the first ferroelectric film.

6. The method of claim 1, wherein in the step (b), a surface roughness of the planarized first ferroelectric film is 1 nm or less in an RMS value.

7. The method of claim 1, wherein the substrate includes a polycrystalline or amorphous film over its surface.

8. The method of claim 1, wherein the step (a) includes forming an amorphous ferroelectric film on the substrate and then subjecting the amorphous ferroelectric film to a heat treatment for crystallization to form the first polycrystalline ferroelectric film.

9. The method of claim 1, wherein the first ferroelectric film and the second ferroelectric film are formed of a ferroelectric material having a perovskite structure.

10. A ferroelectric stacked-layer structure formed on a polycrystalline or amorphous substrate, comprising:
a first polycrystalline ferroelectric film; and
a second thin ferroelectric film stacked on the first ferroelectric film,
wherein the first ferroelectric film has a planarized surface, and
the second ferroelectric film has the same crystalline structure as the first ferroelectric film.

11. The ferroelectric stacked-layer structure of claim 10, wherein a crystal orientation of the first ferroelectric film and a crystal orientation of the second ferroelectric film are aligned.

12. The ferroelectric stacked-layer structure of claim 10, wherein the first ferroelectric film and the second ferroelectric film are formed of the same element.

13. The ferroelectric stacked-layer structure of claim 10, wherein a thickness of the second ferroelectric film is in a range of 1 nm to 60 nm.

14. The ferroelectric stacked-layer structure of claim 10, wherein the second ferroelectric film has a function of reducing a carrier trap level generated by a crystal defect on the planarized surface of the first ferroelectric film.

15. A method for fabricating a field effect transistor, comprising:
(a) forming a gate electrode on a substrate;
(b) forming a first polycrystalline ferroelectric film on the substrate so as to cover the gate electrode;
(c) planarizing a surface of the first ferroelectric film;
(d) stacking, on the planarized first ferroelectric film, a second thin ferroelectric film having the same crystalline structure as the first ferroelectric film;
(e) forming a semiconductor film on the second ferroelectric film; and
(f) forming a source/drain electrode on the semiconductor film,
wherein the first ferroelectric film and the second ferroelectric film constitute a ferroelectric stacked-layer structure which serves as a gate insulating film of the field effect transistor.

16. The method of claim 15, wherein a crystal orientation of the first ferroelectric film and a crystal orientation of the second ferroelectric film are aligned.

17. The method of claim 15, wherein the first ferroelectric film and the second ferroelectric film are formed of the same element.

18. The method of claim 15, wherein a thickness of the second ferroelectric film is in a range of 1 nm to 60 nm.

19. A method for fabricating a ferroelectric capacitor, comprising:
(a) forming a first conductive film on a substrate;
(b) forming a first polycrystalline ferroelectric film on the first conductive film;
(c) planarizing a surface of the first ferroelectric film;
(d) stacking, on the planarized first ferroelectric film, a second thin ferroelectric film having the same crystalline structure as the first ferroelectric film; and
(e) forming a second conductive film on the second ferroelectric film,
wherein the first ferroelectric film and the second ferroelectric film constitute a ferroelectric stacked-layer structure which serves as a capacitor film of the ferroelectric capacitor.

20. The method of claim 19, wherein a crystal orientation of the first ferroelectric film and a crystal orientation of the second ferroelectric film are aligned.

21. The method of claim 19, wherein the first ferroelectric film and the second ferroelectric film are formed of the same element.

22. The method of claim 19, wherein a thickness of the second ferroelectric film is in a range of 1 nm to 60 nm.

23. A field effect transistor of which a gate insulating film has a ferroelectric stacked-layer structure, the ferroelectric stacked-layer structure comprising:
a first polycrystalline ferroelectric film; and
a second thin ferroelectric film stacked on the first ferroelectric film,
wherein the first ferroelectric film has a planarized surface,
the second ferroelectric film has the same crystalline structure as the first ferroelectric film,
a semiconductor film is further formed on the second ferroelectric film, and
an interface between the second ferroelectric film and the semiconductor film serves as a channel of the field effect transistor.

24. A ferroelectric capacitor of which a capacitor film has a ferroelectric stacked-layer structure, the ferroelectric stacked-layer structure comprising:
a first polycrystalline ferroelectric film; and
a second thin ferroelectric film stacked on the first ferroelectric film,
wherein the first ferroelectric film has a planarized surface, and
the second ferroelectric film has the same crystalline structure as the first ferroelectric film.
